(19) United States
(12) Patent Application Publication
(10) Pub. No.: US 2011/0175172 A1
(43) Pub. Date: Jul. 21, 2011

(54) MANUFACTURING A SEMICONDUCTOR DEVICE

(75) Inventor: Takeo MATSUKI, Kanagawa (JP)

(73) Assignee: RENESAS ELECTRONICS CORPORATION, Kanagawa (JP)

(21) Appl. No.: 13/010,233

(22) Filed: Jan. 20, 2011

(30) Foreign Application Priority Data
Jan. 20, 2010 (JP) 2010-010201

(51) Int. Cl. H01L 27/092; H01L 29/78; H01L 21/8238

(52) U.S. Cl. 257/369; 257/413; 438/400; 257/E29.255; 257/E27.064; 257/E21.636

(57) ABSTRACT

There is provided a semiconductor device including: a semiconductor substrate; a gate insulating film formed on the semiconductor substrate; a work function control layer formed on the gate insulating film; a first silicide layer formed on the work function control layer; a polysilicon gate electrode formed on the first silicide layer; and a source region and a drain region formed on opposite sides of a region under the polysilicon gate electrode in the semiconductor substrate.

This application is based on Japanese patent application No. 2010-10201, the content of which is incorporated hereinto by reference.

### BACKGROUND

1. Technical Field

The present invention relates to a semiconductor device and a method of manufacturing the semiconductor device.

2. Related Art

There has been known a FET having a gate electrode structure in which a gate insulating film, a metal layer, and a semiconductor layer are formed in this order on a semiconductor substrate.

For instance, Japanese Unexamined Patent Publication No. 2008-91501 discloses a gate electrode structure having a lamination structure of a gate insulating film 59/a threshold electrode (or work function electrode) 52 (55)/an intermediate layer 53 (56)/a wiring metal layer 54 (57) (FIG. 1 of Japanese Unexamined Patent Publication No. 2008-91501).

It is described that any one of Ta, TaN, TaSi, TaSi₂, and TaSiₓN_{y} is preferable as the threshold electrode (or the work function electrode) 52 of an N-type FET (paragraph [0038] of Japanese Unexamined Patent Publication No. 2008-91501). Also, it is described that anyone of Ru, RuO₂, TiN, and TiSiₓN_{y} is preferable as the threshold electrode (or the work function electrode) 55 of a P-type FET (paragraph [0040] of Japanese Unexamined Patent Publication No. 2008-91501). Further, it is described that a polycrystalline TiN film or polycrystalline TaN film is preferable as the intermediate layer 53 of the N-type FET and the intermediate layer 56 of the P-type FET (paragraphs [0039] and [0041] of Japanese Unexamined Patent Publication No. 2008-91501).

Japanese Unexamined Patent Publication No. 2007-158065 discloses a gate electrode structure having a lamination structure of a gate insulating film 112 (132)/a barrier film 114 (134)/a first silicide layer 116a (136a)/a second silicide layer 116b (136b) (FIG. 5C of Japanese Unexamined Patent Publication No. 2007-158065). It is described that a polycrystalline silicon layer may be provided between the first silicide layer 116a (136a) and the second silicide layer 116b (136b) (paragraph [0045] of Japanese Unexamined Patent Publication No. 2007-158065).

It is described that the barrier film of an N-type FET is formed of at least one metal nitride selected from the group consisting of TiN, TaN, and WN (paragraph [0020] of Japanese Unexamined Patent Publication No. 2007-158065). Also, it is described that the barrier film of a P-type FET may be the metal nitride film same as that of the barrier film of the N-type FET (paragraph [0036] of Japanese Unexamined Patent Publication No. 2007-158065).

Also, another technically-related FET is disclosed in Japanese Unexamined Patent Publication No. 2005-243664.

The present inventor has recognized as follows. Agate electrode of a FET is required to have the following properties.

Requirement 1: A low threshold voltage. In the case of a CMOSFET, both of an N-type and a P-type are required to satisfy the present requirement. In order to attain the low threshold value, it is desirable that a work function exhibited by a gate material is about 4.1 to 4.3 eV in the N-type FET and about 4.9 to 5.1 eV in the P-type FET.

Requirement 2: Low gate electrode resistivity. This property is necessary for causing a current to flow in a longitudinal direction of the gate electrode. In conventional polysilicon gate electrodes, relatively high resistivity of polysilicon has been effectively lowered by siliciding a surface of a polysilicon film.

Requirement 3: Low resistance in a perpendicular direction (direction perpendicular to the substrate) of a gate electrode structure in which layers of a plurality of types are laminated. This property is required for effectively applying a voltage to a gate insulating film by charges accumulated after being supplied in the longitudinal direction of the gate electrode.

In the case of the FET disclosed in Japanese Unexamined Patent Publication No. 2008-91501, TiN or TiSiN is used for the P-type FET. It has been known that deviation from the appropriate threshold voltage for the P-type FET occurs when a high temperature heat treatment is performed in the FET.

Also, in the FET disclosed in Japanese Unexamined Patent Publication No. 2008-91501, TiN or TaN is formed as the intermediate layer 53 (56) on the threshold electrode (or the work function electrode) 52 (55), and the wiring metal layer 54 (57) are formed on the intermediate layer 53 (56). As the wiring metal layers 54 and 57, W, WSi₂, Mo, Ta, Ru, and Si are exemplified. However, since the use of W, WSi₂, Mo, Ta, Ru, or Si in the gate first process entails various troubles such as a trouble in dry etching processability, it is difficult to simply adopt the conventional CMOS process.

Meanwhile, in the case where Si is used for the wiring metal layer 54 (57), large resistance is generated in a surface boundary between the wiring metal layer 54 (57) and the intermediate layer 53 (56) when a current is flown in the perpendicular direction. In short, it is difficult to satisfy Requirement 3.

In the case of the FET disclosed in Japanese Unexamined Patent Publication No. 2007-158065, at least one specie selected from the group consisting of TiN, TaN, and WN is used for the barrier film of the P-type FET. In such case, deviation from the appropriate threshold voltage for the P-type FET occurs when a high temperature heat treatment is performed.

In one embodiment, there is provided a semiconductor device including: a semiconductor substrate; a gate insulating film formed on the semiconductor substrate; a work function control layer formed on the gate insulating film; a first silicide layer formed on the work function control layer; a polysilicon gate electrode formed on the first silicide layer; and a source region and a drain region formed on opposite sides of a region under the polysilicon gate electrode in the semiconductor substrate.

In another embodiment, there is provided a method of manufacturing a semiconductor device including: forming an element isolation on a semiconductor substrate; forming a p-type or n-type well in a region separated by the element isolation; forming a film to be used as a gate insulating film on the p-type or n-type well; forming a first metal layer on the film to be used as a gate insulating film on the p-type well and a second metal layer on the film to be used as a gate insulating film on the n-type well as metal layers to be used as work function control layers; forming a first silicide layer on the metal layers; forming a polysilicon layer to be used as a gate electrode on the first silicide layer; and selectively eliminating the polysilicon layer, the first silicide layer, and the metal layer.

### SUMMARY

The semiconductor device of the present invention includes a first silicide layer between a work function control layer and a polysilicon gate electrode. Owing to the structure, it is possible to reduce resistance in a perpendicular direction (direction perpendicular to the substrate) of a gate electrode structure in which a plurality of types of layers are laminated, thereby promising effects such as high speed operation of the circuit.

According to the present invention, the resistance in the perpendicular direction of the gate electrode structure is reduced.

### BRIEF DESCRIPTION OF THE DRAWINGS

The above and other objects, advantages, and features of the present invention will be more apparent from the following description of certain preferred embodiments taken in conjunction with the accompanying drawings, in which:

FIG. 1 is a sectional view schematically showing one example of a semiconductor device according to a first embodiment;

FIG. 2 is a sectional view schematically showing one example of a semiconductor device according to a second embodiment;

FIG. 3 is a sectional view schematically showing one example of a manufacturing process of the semiconductor device according to the second embodiment;

FIG. 4 is a sectional view schematically showing one example of the manufacturing process of the semiconductor device according to the second embodiment;

FIG. 5 is a sectional view schematically showing one example of the manufacturing process of the semiconductor device according to the second embodiment;

FIG. 6 is a sectional view schematically showing one example of the manufacturing process of the semiconductor device according to the second embodiment; and

FIG. 7 is a sectional view schematically showing one example of the manufacturing process of the semiconductor device according to the second embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments shown for explanatory purposes.

Hereinafter, embodiments of the present invention will be described with reference to the drawings. The same constitution elements are denoted by identical reference numerals in all of the drawings, and, accordingly, description of such elements will not be repeated.

### First Embodiment

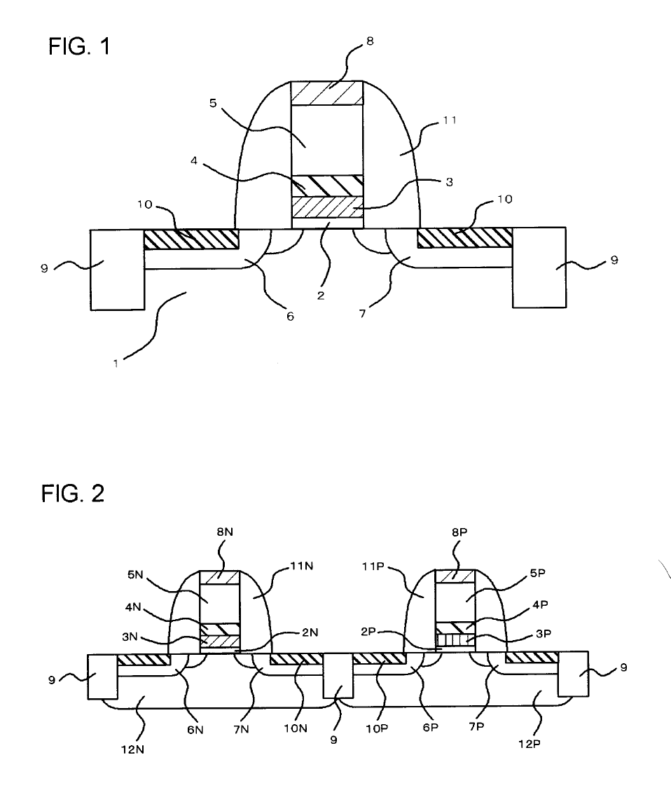

FIG. 1 is a sectional view schematically showing one example of a semiconductor device according to a first embodiment. The semiconductor device of the present embodiment may be an N-type FET or a P-type FET.

As shown in FIG. 1, the semiconductor device of the present embodiment has a semiconductor substrate 1, a gate insulating film 2 formed on the semiconductor substrate 1, a work function control layer 3 formed on the gate insulating film 2, a first silicide layer 4 formed on the work function control layer 3, a polysilicon gate electrode 5 formed on the first silicide layer 4, a source region 6 and a drain region 7 formed on opposite sides of a region under the polysilicon gate 5 in the semiconductor substrate 1.

The semiconductor device may have a second silicide layer 8 on the polysilicon gate electrode 5. Also, the semiconductor device may have an element isolation 9 and a third silicide layer 10. Further, the semiconductor device may have a side wall film 11 formed of a silicon nitride film, for example, on side faces of the gate insulating film 2, the work function control layer 3, the first silicide layer 4, the polysilicon gate electrode 5, and the second silicide layer 8.

As the gate insulating film 2, a material having a dielectric constant higher than SiO₂, such as a silicon oxynitride film, an Hf oxide, and an La (rare earth) oxide, may be used.

In the case where the semiconductor device of the present embodiment is the N-type FET, it is desirable that the work function control layer 3 contains at least one of TaSiN, TaSi, and TaSi₂. The N-type FET may have a structure in which a layer including at least one of Ru, Pt, and Ir is laminated on the layer containing at least one of TaSiN, TaSi, and TaSi₂.

In the case where the semiconductor device of the present embodiment is the P-type FET, it is desirable that the work function control layer 3 contains at least one of Ru, Pt, and Ir. The P-type FET may have a structure in which a layer including at least one of TaSiN, TaSi, and TaSi₂ is laminated on the layer containing at least one of Ru, Pt, and Ir.

The first silicide layer 4 is formed of at least one of Ti silicide, Co silicide, Ni silicide, Ta silicide, W silicide, and Mo silicide. The second silicide 8 and the third silicide 10 may be Ni silicide, NiPt silicide, or the like without particular limitation thereto.

Since each of semiconductor devices of the present embodiment, which has the above-described structure, has the work function control layer 3 formed of the material suitable for each of the N-type FET and the P-type FET, an efficient reduction in threshold voltage is realized in each of the N-type FET and the P-type FET. In short, above-mentioned Requirement 1 is satisfied.

Since it is possible to provide the second silicide layer 8 on the polysilicon gate electrode 5 in the semiconductor device of the present embodiment, a reduction in resistivity of the polysilicon gate electrode 5 is realized. In short, above-mentioned Requirement 2 is satisfied.

Further, since the semiconductor device of the present embodiment has the first silicide layer 4 between the work function control layer 3 and the polysilicon gate electrode 5, it is possible to reduce resistance in the perpendicular direction (direction perpendicular to the substrate) of the gate electrode structure in which the plurality of types of layers are laminated. In short, above-mentioned Requirement 3 is satisfied.

According to the semiconductor device of the present embodiment, the resistance in the perpendicular direction of the gate electrode structure is reduced without impairing the properties that the gate electrode is required to have. As a result, it is possible to efficiently apply a voltage to the gate insulating film, thereby promising effects such as a high speed operation of the circuit.

Since a method of manufacturing the semiconductor device of the present embodiment is realized in accordance with a method of manufacturing a semiconductor device of the second embodiment described below, the manufacturing method is not described in the present embodiment.

### Second Embodiment

FIG. 2 is a sectional view schematically showing one example of a semiconductor device of the present embodiment. The semiconductor device of the present embodiment is a CMOSFET having the N-type FET and the P-type FET of the first embodiment.

Hereinafter, a method of manufacturing the semiconductor device of the present embodiment will be described.

The method of manufacturing the semiconductor device of the present embodiment includes an element isolation formation step of forming an element isolation on a semiconductor substrate, a well formation step of forming p-type and n-type wells in a region separated by the element isolation, a gate insulating film formation step of forming a film to be used as a gate insulating film on the p-type and n-type wells, a work function control layer formation step of forming a first metal layer on the film to be used as the gate insulating film on the p-type well and a second metal layer on the film to be used as the gate insulating film on the n-type well as metal layers to be a work function control layer, a first silicide layer formation step of forming a first silicide layer on the metal layer, a gate electrode formation step of forming a polysilicon layer to be used as a gate electrode on the first silicide layer, and an etching step of selectively eliminating the polysilicon layer, the first silicide layer, and the metal layer.

The method of manufacturing the semiconductor device of the present embodiment may include a step of forming a second silicide layer on the polysilicon layer after the etching step.

It is possible to realize the method of manufacturing the semiconductor device of the first embodiment by replacing the well formation step with a step of forming the p-type or n-type well.

Hereinafter, one example of the method of manufacturing the semiconductor device of the present embodiment will be described.

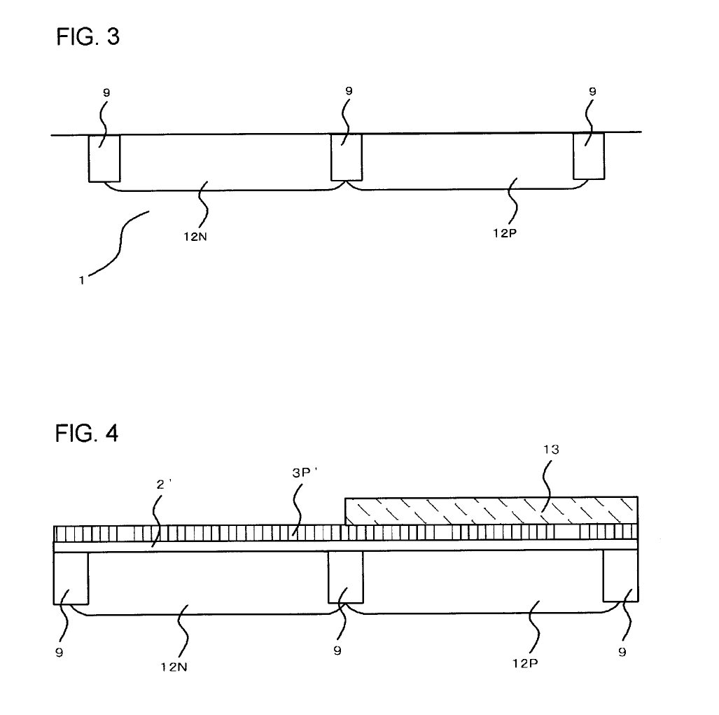

As shown in FIG. 3, an element isolation 9 and a p-type well 12N and an n-type well 12P are formed on a semiconductor substrate 1 (Si substrate, for example) by a known technique (element isolation formation step, well formation step). As shown in FIG. 3, the p-type well 12N and the n-type well 12P are separated by the element isolation 9.

After that, a film 2′ to be the gate insulating film shown in FIG. 4 is formed on the p-type well 12N and the n-type well 12P (gate insulating film formation step).

As a material for the film 2′ to be used as the gate insulating film, a material having a dielectric constant higher than SiO₂, such as a silicon oxynitride film, an Hf oxide, and an La (rare earth) oxide, may be used as described in the first embodiment. A method for forming the film 2′ from the material is not particularly limited, and a known technique may be employed. For example, the film 2′ is formed as described below in the case of selecting HfSiO obtained by mixing HfO₂ with Si.

After forming a thin SiO₂ film having a thickness of about 0.5 to 1.0 nm as a surface boundary SiO₂ film on the Si substrate (semiconductor substrate 1), a film of HfSiO is formed on the surface boundary SiO₂ film. The surface boundary SiO₂ is disposed for the purpose of suppressing diffusion of Hf of HfSiO into the Si substrate (semiconductor substrate 1). Next, HfSiO is formed into HfSiON as required by nitriding HfSiO by a heat treatment under an ammonium atmosphere or with nitrogen plasma. Next, for the purposes of reducing defects in the film and increasing film density, a high temperature heat treatment is performed at a temperature of about 100° C. By the nitriding, it is possible to attain a higher dielectric constant of HfSiO and to suppress crystallization and phase separation of HfSiO in a heat treatment to be performed later on.

After the gate insulating film formation step, a first metal layer 3N′ is formed on the film 2′ on the p-type well 12N and a second metal layer 3P′ is formed on the film 2′ on the n-type well 12P as metal layers to be used as the work function control layers as shown in FIG. 6 (work function control layer formation step). A first metal forming the first metal layer 3N′ may contain at least one of TaSiN, TaSi, and TaSi₂. A second metal forming the second metal layer 3P′ may contain at least one of Ru, Pt and Ir.

A method for forming the first metal layer 3N′ and the second metal layer 3P′ is not particularly limited, and a known technique may be employed. For example, the producing process may include a step of selectively forming the second metal layer 3P′ on the film 2′ to be used as the gate insulating film on the n-type well 12P and a step of forming the first metal layer 3N′ on the film 2′ to be used as the gate insulating film on the p type well 12N.

As a specific example, the second metal layer 3P′ is formed on the film 2′ to be used as the gate insulating film as shown in FIG. 4. For example, MOCVD (Metal Organic Chemical Vapor Deposition), ALD (Atomic Layer Deposition), reactive sputtering, or the like may be employed. A film thickness may be equal to or more than 5 nm and equal to or less than 20 nm.

After that, a SiN film 13 is selectively formed on the second metal layer 3P′ on the N-type well 12P as shown in FIG. 4. The film formation may be realized by employing CVD (Chemical vapor Deposition), photolithography, and etching, for example. The SiN film 13 to be formed herein is desirable since it is possible to form the SiN film 13 at a temperature of 500° C. or less.

After that, the second metal layer 3P′ on the p-type well 12N is eliminated by using the SiN film as a mask. It is possible to realize the elimination by employing a known technique, and it is desirable to select a method that minimizes the damage to be caused on the film 2′ (HfSiON film, for example) disposed under the second metal layer 3P′ to be used as the gate insulating film. For example, the elimination may be realized by dry etching (reactive ion etching, for example) using the SiN film 13 as a mask.

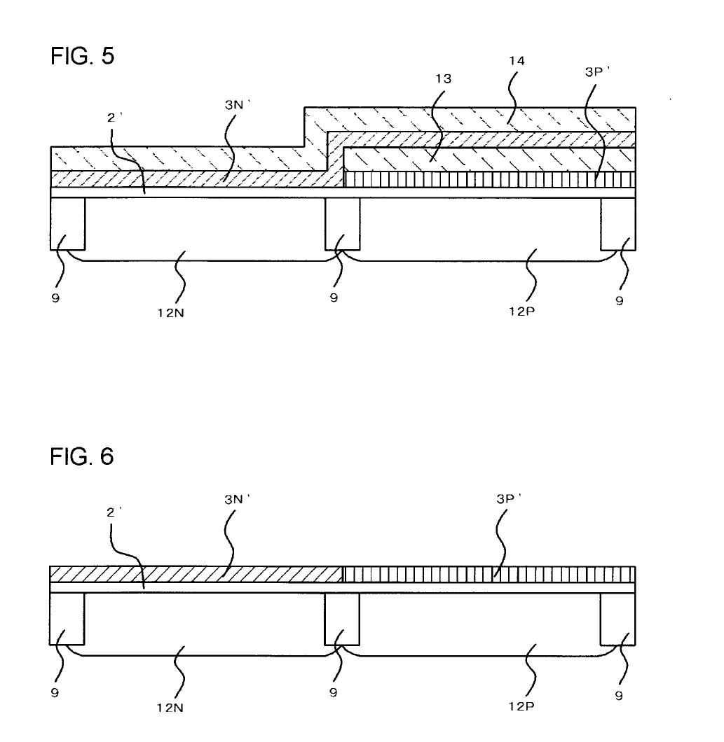

Next, the first metal layer 3N′ shown in FIG. 5 is formed on the film 2′ on the p-type well 12N and the SiN film 13 positioned above the n-type well 12P. For example, MOCVD, ALD, or reactive sputtering may be employed. A film thickness may be equal to or more than 5 nm and equal to or more than 10 nm.

Next, the structure shown in FIG. 5 is obtained by forming a SiN film 14 on the first metal layer 3N′. After that, the SiN film 14 and the first metal layer 3N′ positioned above the n-type well 12P are selectively eliminated by employing photolithography and etching. Also, the structure shown in FIG. 6 is obtained by eliminating the SiN film 14 positioned above the p-type well 12N and the SiN film 13 positioned above the n-type well 12P.

The work function control layer formation step may be a step of forming a structure in which the first metal layer 3N′ and a layer containing at least one of Ru, Pt, and Ir formed on the first metal layer 3N′ are formed on the film 2′ on the p-type well 12N and a structure in which the second metal layer 3P′ and a layer containing at least one of TaSiN, TaSi, and TaSi₂ are formed on the film 2′ on the n-type well 12P. It is possible to realize the step by combining photolithography and etching in an appropriate manner in accordance with the above-described technique.

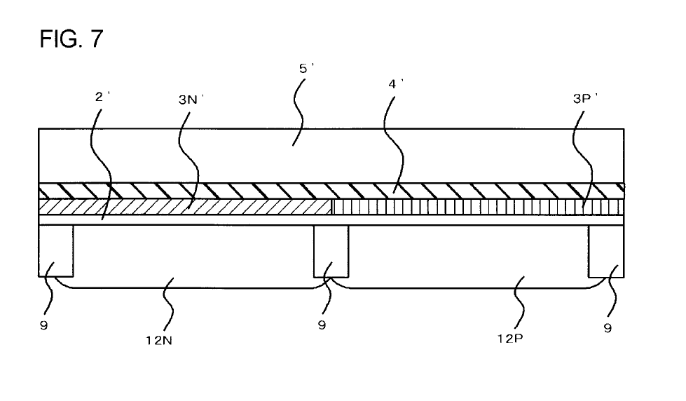

After the work function control layer formation step (after obtaining the structure shown in FIG. 6, for example), a first silicide layer 4′ shown in FIG. 7 is formed on the metal layers which are the first metal layer 3N′ and the second metal layer 3P′ (first silicide layer formation step). A film thickness of the first silicide layer 4′ may be equal to or more than 3 nm and equal to or less than 10 nm, for example. The first silicide layer 4′ is formed of at least one of Ti silicide, Co silicide, Ni silicide, Ta silicide, W silicide, and Mo silicide. A method for forming the first silicide layer 4′ is not particularly limited, and the first silicide layer 4′ may be formed in the manner as described below.

A film of a metal for silicide is formed on the first metal layer 3N′ and the second metal layer 3P′, for example, and a polysilicon layer is formed on the metal film, followed by a heat treatment at a temperature appropriate for the type of the metal for silicide. A temperature of the heat treatment may be equal to or more than 400° C. and equal to or less than 800° C. in the case where Ni is selected as the metal for silicide, equal to or more than 700° C. and equal to or less than 800° C. in the case where Co is selected as the metal for silicide, equal to or more than 900° C. and equal to or less than 1000° C. in the case where Ta is selected as the metal for silicide, and equal to or more than 800° C. and equal to or less than 900° C. in the case where Ti is selected as the metal for silicide.

As another method for forming the first silicide layer 4′, a film having a silicide composition is formed on the first metal layer 3N′ and the second metal layer 3P′ by employing PDV (Physical Vapor Deposition) or CVD, followed by a heat treatment. Alternatively, a film of a silicide composition is formed, and a polysilicon layer is formed, followed by a heat treatment.

A polysilicon layer 5′ to be used as a polysilicon gate electrode is formed on the first silicide layer 4′ by employing CVD (gate electrode formation step). A film thickness may be equal to or more than 30 nm and equal to or less than 50 nm.

The polysilicon layer 5′, the first silicide layer 4′, the metal layers (first metal layer 3N′ and second metal layer 3P′), and the film 2′ are selectively eliminated by employing photolithography and etching (etching step). Thus, gate insulating films 2N and 2P, work function control layers 3N and 3p, first silicide layers 4N and 4P, and polysilicon gate electrodes 5N and 5P having shapes shown in FIG. 2 are formed.

In the case where the dry etching method using plasma is employed for the selective elimination of the layers, particularly in the case of using CF₄, CHF₃, or the like as a gas containing carbon, there is a risk that polymerization product formed by an element contained in the etching object and the gas remains on a wafer surface. In the case of using a hydrofluoric acid solution or a buffered hydrofluoric acid solution in order to eliminate the residual product, it is desirable that the first silicide layer 4′ is Ta silicide, W silicide, or Mo silicide since Ti silicide and Co silicide are easily dissolved into the hydrofluoric acid solution. It is desirable that a resist mask elimination processing performed after the dry etching is etching with hydrogen plasma, not etching with oxygen plasma.

After that, a gate side wall films 11N and 11P, a source drain extension region, source/drain regions 6N, 7N, 6P, and 7P shown in FIG. 2 are formed by a known technique. In the formation, a heat treatment is performed at a temperature of 950° C. or more for a predetermined period of time for activation of a dopant. Also, by employing a known salicide technique, second silicide layers 8N and 8P and third silicide layers 10N and 10P are selectively formed by the same processing on surfaces of the source/drain regions 6N, 7N, 6P, and 7P and the polysilicon gate electrodes 5N and 5P. Thus, the structure shown in FIG. 2 is obtained. After that, an interlayer insulating film, a wiring, a via hole, and the like (not shown) are formed by a known technique.

As described above, the method of manufacturing the semiconductor device of the present embodiment includes the heat treatment that has the risk of deviating the threshold voltage from the appropriate range in the case where Tin, TiSiN, TaN, WN, or the like is used for the work function control layer 3P′ for the P-type FET after the work function control layer formation step. More specifically, the manufacturing method includes the heat treatment that is performed at a temperature of 950° C. or more for a predetermined time period. However, since the material used for the electrode structure of the P-type FET is appropriately selected, it is possible to prevent the deviation from an appropriate threshold voltage range for the P-type FET which is otherwise caused by the heat treatment. Also, the semiconductor device of the present embodiment realizes the effects same as those of the first embodiment.

It is apparent that the present invention is not limited to the above-described embodiments and may be modified and changed without departing from the scope and spirit of the invention.

What is claimed is:

1. A semiconductor device comprising:
a semiconductor substrate;
a gate insulating film formed on said semiconductor substrate;
a work function control layer formed on said gate insulating film;
a first silicide layer formed on said work function control layer;
a polysilicon gate electrode formed on said first silicide layer; and
a source region and a drain region formed on opposite sides of a region under said polysilicon gate electrode in said semiconductor substrate.

2. The semiconductor device according to claim 1, further comprising a second silicide layer formed on said polysilicon gate electrode.

3. The semiconductor device according to claim 1, wherein
said semiconductor device is an N-type FET, and
said work function control layer contains at least one of TaSiN, TaSi, and TaSi₂.

4. The semiconductor device according to claim 1, wherein
said semiconductor device is a P-type FET, and
said work function control layer contains at least one of Ru, Pt, and Ir.

5. The semiconductor device according to claim 1, wherein said semiconductor device is a CMOSFET comprising a N-type FET and a P-type FET;
said work function control layer of said N-type FET contains at least one of TaSiN, TaSi, and TaSi₂; and
said work function control layer of said P-type FET contains at least one of Ru, Pt, and Ir.

6. A method of manufacturing a semiconductor device comprising:
forming an element isolation on a semiconductor substrate;
forming a p-type or n-type well in a region separated by said element isolation;
forming a film to be used as a gate insulating film on said p-type or n-type well;
forming a first metal layer on said film to be used as a gate insulating film on said p-type well and a second metal layer on said film to be used as a gate insulating film on said n-type well as metal layers to be used as work function control layers;
forming a first silicide layer on said metal layers;
forming a polysilicon layer to be used as a gate electrode on said first silicide layer; and
selectively eliminating said polysilicon layer, said first silicide layer, and said metal layer.

7. The method of manufacturing a semiconductor device according to claim 6, wherein
said forming the well is forming p-type and n-type wells; and
said forming the first metal layer and the second metal layer includes:
selectively forming said second metal layer on said film to be used as the gate insulating film on said n-type well by photolithography and etching; and
forming said first metal layer on said film to be used as the gate insulating film on said p-type well by photolithography and etching.

8. The method of manufacturing a semiconductor device according to claim 6, wherein
a first metal forming said first metal layer contains at least one of TaSiN, TaSi, and TaSi₂:
a second metal forming said second metal layer contains at least one of Ru, Pt, and Ir.

9. The method of manufacturing a semiconductor device according to claim 6, further comprising forming a second silicide layer on said polysilicon layer after said selectively eliminating.

10. The method of manufacturing a semiconductor device according to claim 6, further comprising heating at 950° C. or more after said forming the first metal layer and the second metal layer.
